(19) United States
(12) Patent Application Publication
(10) Pub. No.: US 2007/0153478 A1
(43) Pub. Date: Jul. 5, 2007

(54) Method for controlling fan rotational speed in electronic system and electronic system applying the same

(75) Inventor: Min Yu Lu, Taoyuan County (TW)

Correspondence Address: QUINTERO LAW OFFICE, PC, 2210 MAIN STREET, SUITE 200, SANTA MONICA, CA, 90405, US

(73) Assignee: LITE-ON TECHNOLOGY CORPORATION, TAIPEI (TW)

(21) Appl. No.: 11/618,966

(22) Filed: Jan. 2, 2007

(30) Foreign Application Priority Data
Jan. 2, 2006 (TW) TW95100045

(51) Int. Cl. H05K 7/20

(52) U.S. Cl. 361/697

(57) ABSTRACT

A method for controlling the rotational speed of a cooling fan in an electronic system is disclosed, wherein the electronic system comprises a CPU, a cooling module comprising the cooling fan and a cooling fin. The method includes measuring the voltage of the CPU to obtain the power of the CPU, obtaining a first rotational speed based on the power of the CPU, and correcting the first rotational speed based on stored characteristic parameter(s) of the electronic system. An electronic system utilizing the method is further disclosed.

### BACKGROUND OF THE INVENTION

1. Field of the Invention

The invention relates to cooling in electronic systems and more particularly to a method for controlling rotational speed of a cooling fan in an electronic system and an electronic system applying the same.

2. Description of the Related Art

FIG. 1 is a block diagram of an electronic system 100. The electronic system 100 comprises a CPU 10, a cooling fin 12 and a cooling fan 14. The cooling fin 12 and cooling fan 14 make up a cooling module to provide dispersion of thermal energy produced by the CPU 10 to control temperatures in the electronic system 100. The electronic system has no control of rotational speed of the cooling fan 14, irrespective of operating speed of the CPU 10. The rotational speed of the cooling fan is typically set high enough to compensate CPU 10 operating at a high speed. However, this may exceed the normal cooling requirement of the CPU 10, consuming excess power and generating noise.

FIG. 2 is a block diagram of another conventional electronic system 200, differing from system 100 in addition of a fan control and detection device 16. The fan control and detection device 16 is controlled by a BIOS 18 which stores a formula for the fan rotational speed corresponding to CPU temperature. When the CPU 10 is operating, the fan control and detection device 16 detects the temperature T_{CPU} of the CPU 10 and transmits CPU-temperature data D_{TCPU} to BIOS 18. The BIOS 18 then refers to the stored formula of fan rotational speed corresponding to CPU temperature, and outputs fan-rotational-speed data D_{FAN} to the fan control and detection device 16. The fan control and detection device 16 then outputs a fan-rotation-speed control signal S_{FAN} according to the fan-rotational-speed data D_{FAN} to control the rotational speed of the cooling fan 14

However, there is difficulty in designing the formula of fan rotational speed corresponding to CPU temperature stored in BIOS 18. Consideration factors in setting the rotational speed of a fan include the cooling efficiency of a cooling module (the cooling fin and the cooling fan), environmental temperature and characteristics of the electronic system where the cooling fan is disposed. The cooling efficiency of a cooling module depends on manufacturer and model number nowadays. When a manufacturer sells an electronic system, it is able to measure the electronic system so as to design formula of fan rotational speed corresponding to CPU temperature. However, when a manufacturer sells a motherboard, it is imposable to predict what cooling module will be collocated with the motherboard. Further, since the fan control and detection device adjusts the rotational speed of the cooling fan 12 after detecting the temperature of the CPU 10, variation in CPU temperature is not controlled in time.

Accordingly, an electronic system controlling rotational speed of a cooling fan disposed therein by considering not only CPU temperature but also cooling efficiency of a cooling module accompanying the CPU and the characteristics of the environment of the electronic system, and gripping the operation situation of the CPU, is called for.

### BRIEF SUMMARY OF THE INVENTION

The invention discloses a method for controlling fan rotational speed in an electronic system. The method is based mainly on CPU power and makes modification according to characteristics of the electronic system such as cooling efficiency of a cooling module and environmental temperature of the electronic system, thus achieving an ideal and instantaneous adjustment of fan rotational speed. The invention further discloses an electronic system employing the method.

The invention provides a method for controlling fan rotational speed in an electronic system, wherein the electronic system comprises a CPU and a cooling module comprising a cooling fan and a cooling fin. The method comprises measuring the central voltage of the CPU, obtaining a first fan rotational speed, and modifying the first fan rotational speed according to characteristics data of the electronic system.

The invention provides a electronic system comprising a CPU, a cooling module comprising a cooling fin and a cooling fan, a fan control and detection device coupled to the CPU and the cooling fan, detecting the central voltage of the CPU to output a voltage data and controlling the rotational speed of the cooling fan according to final fan-rotational-speed data, a memory storing system characteristic data, and a calculation module coupled to the fan control and detection device to generate the final fan-rotational-speed data according to the voltage data and system characteristic data.

In an embodiment of the invention, the electronic system further comprises a device to detect CUP temperature and environmental temperature, such that the calculation module calculates cooling efficiency of the cooling module as system characteristics according to CPU power, CPU temperature, and environmental temperature, obtains a first fan rotational speed data, and modifies the first fan rotational speed to the final fan-rotational-speed data.

### BRIEF DESCRIPTION OF THE DRAWINGS

The invention can be more fully understood by reading the subsequent detailed description and examples with references made to the accompanying drawings, wherein:

FIG. 1 is a block diagram of a conventional electronic system;

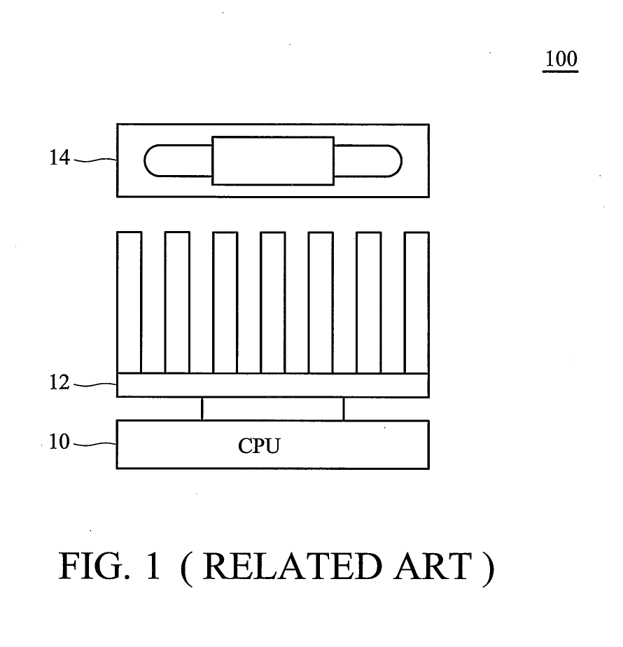

FIG. 2 is a block diagram of another conventional electronic system;

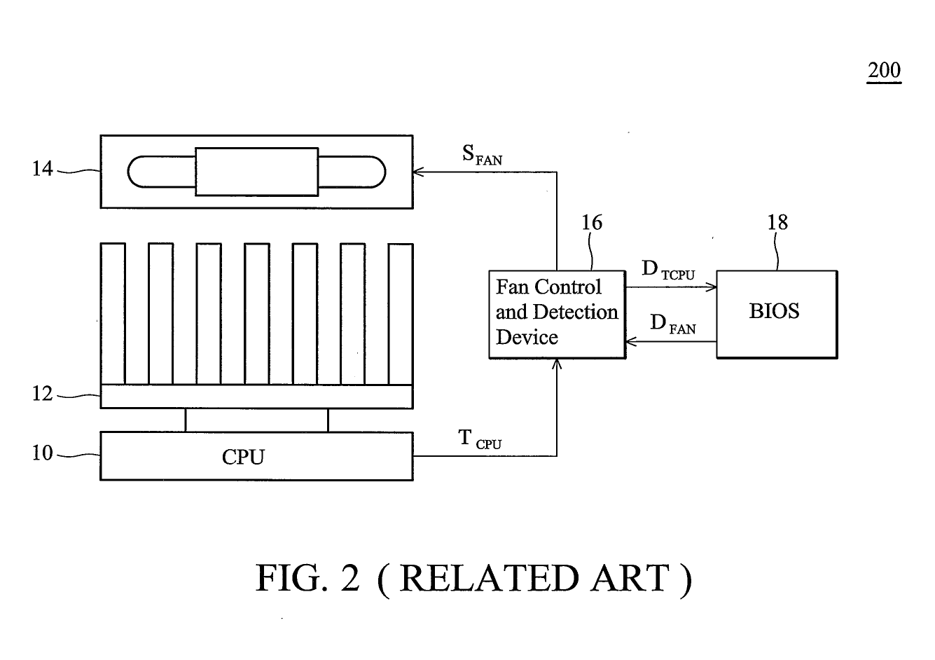

FIG. 3 is a block diagram of an electronic system in accordance with an embodiment of the invention;

FIG. 4 is a flowchart of a calculation module generating final fan-rotational-speed data according to voltage data and system characteristic data;

FIG. 5 is an exemplary drawing showing a CPU load curve;

FIG. 6 is a flowchart of a calculation module modifying first fan-rotational-speed data to final fan-rotational-speed data according to system characteristic data in accordance with an embodiment of invention where the system characteristic comprises a first system characteristic data and a second system characteristic data;

FIG. 7 shows an electronic system where system characteristic data comprises a cooling efficiency parameter and environmental temperature in accordance with an embodiment of the invention;

FIG. 8 is a flowchart of a modulation module calculating a cooling efficiency parameter according environmental temperature data and CPU temperature data; and

FIG. 9 shows an exemplary CPU thermal curve for a CPU.

### DETAILED DESCRIPTION OF THE INVENTION

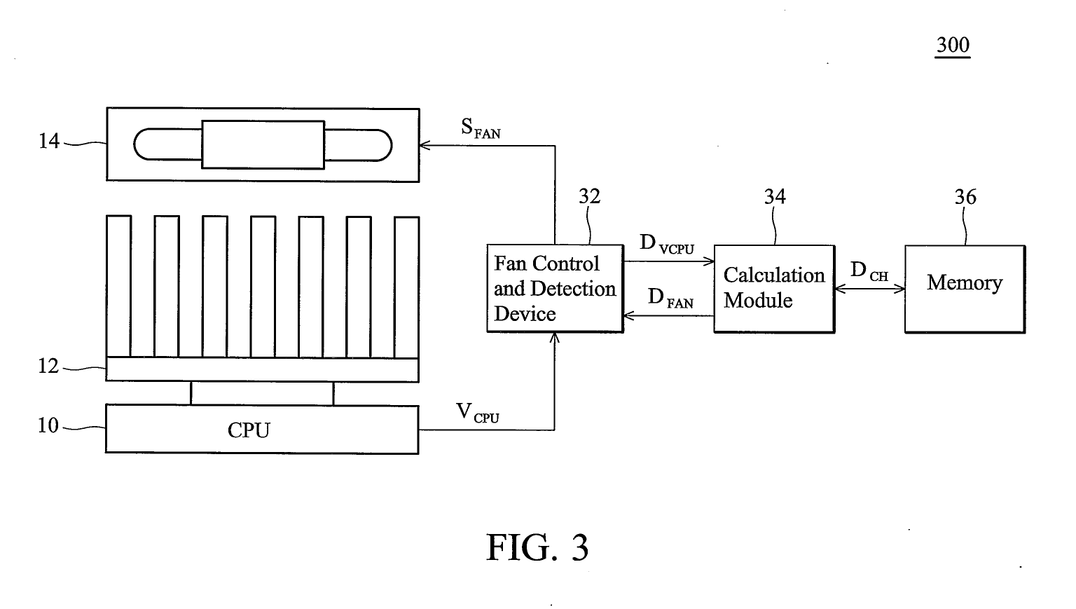

FIG. 3 is a block diagram of an electronic system 300 in accordance with an embodiment of the invention. The electronic system 200 comprises a CPU 10, a cooling fin 12 and a cooling fan 14, making up a cooling module to provide thermal dispersion of the CPU 10, a fan control and detection device 32 coupled to the CPU 10 and the cooling fan 14, a calculation module 34 coupled to the fan control and detection device 32, and a memory 36 storing system characteristic data D_{CH} such as cooling efficiency of the cooling module and environmental temperature of the electronic system 300. The calculation module 34, for example, is a BIOS cooperating with an environmental monitor device inherent in the electronic system 300, or a combination of conventional logic components, or a single chip computer integrated with conventional logic components. The memory 36 can be combined into the calculation module 34 or independent of the calculation module 34. Further, multiple memories 36 can be disposed in the electronic system 300, including a first memory independent of the calculation module 34 and a second memory combined into the calculation module 34. Some system characteristic data stored in the memory 36, for example, environmental temperature, can be obtained by various system characteristic detection devices (not shown in FIG. 3), and some other system characteristic data, for example, a cooling efficiency parameter, can be calculated by the calculation module 34 based on the data detected by the system characteristic detection devices.

The fan control and detection device 32 detects central voltage V_{CPU} of the CPU 10 and outputs voltage data D_{VCPU} to the calculation module 34. The calculation module 34 generates final fan-rotational-speed data D_{FAN} according to the voltage data D_{VCPU} and the system characteristic data D_{CH} stored in the memory 36, and then provides the final fan-rotational-speed data D_{FAN} to the fan control and detection device 32. The fan control and detection device 32 then generates a speed control signal S_{FAN} to the cooling fan 14 according to the final fan-rotational-speed data D_{FAN} to control the rotational speed of the cooling fan 14.

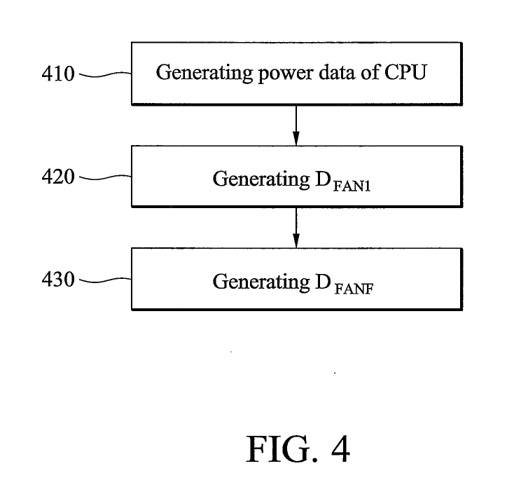

FIG. 4 is a flowchart of calculation module 34 generating the final fan-rotational-speed data D_{FAN} according to the voltage data D_{VCPU} and the system characteristic data D_{CH}. First, in step 410, the calculation module 34 generates power data of the CPU 10 according to the voltage data D_{VCPU}. Next, in step 420, the calculation module 34 generates first fan-rotational-speed data D_{FAN1} according to the power data. Finally, in step 430, the calculation module 34 modifies the first fan-rotational-speed data D_{FAN1} into final fan-rotational-speed data D_{FANF} according to the system characteristic data D_{CH}.

In step 410, the calculation module 34 generates power data according to the voltage data D_{VCPU}, the central voltage of a CPU reflecting the power consumption of the CPU. Accordingly, the method for obtaining the power data according to the voltage data D_{VCPU} for the calculation module 34, for example, refers to a CPU load curve of the CUP 10. A CPU load curve shows central current verse central voltage for a CPU, providing power data corresponding to the central voltage of the CPU.

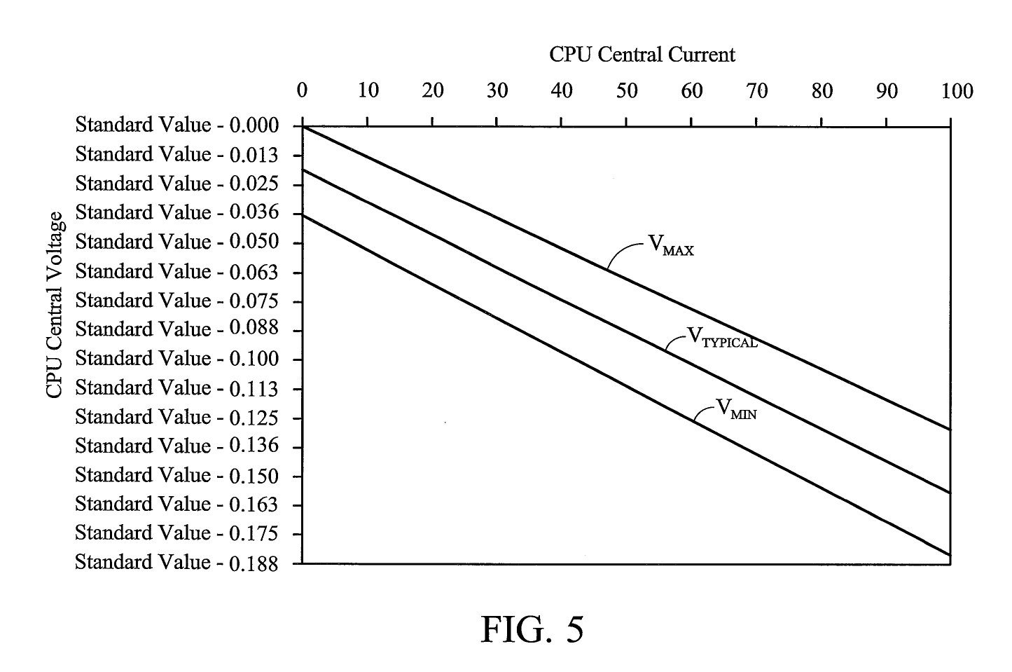

FIG. 5 is an exemplary drawing showing a CPU load curve. Line V_{TYPICAL} is a typical operating curve of a CPU, and in reality the CPU load curve lies between the lines V_{MAX} and V_{MIN}. In one embodiment, the CPU power data is obtained by referring to the line V_{TYPICAL}. In the invention, CPU load curve data is stored in memory 36 and provided to the calculation module 34 before the calculation module 34 obtains the power data according to the voltage data D_{VCPU}.

In step 420, calculation module 34 then generates first fan-rotational-speed data D_{FAN1} according to the power data. The first fan-rotational-speed data D_{FAN1} is obtained according to standard CPU power-fan rotational speed formula data corresponding to different power settings for a standard CPU of the same type as CPU 10 under standard conditions. More specifically, the standard CPU power-fan rotational speed formula data comprises predetermined fan rotational speeds corresponding to different power for a standard CPU of the same type as the CPU 10 allocated with a standard cooling module in a standard electronic system at a standard environmental temperature. The predetermined fan rotational speed is typically a minimum rotational speed at which a cooling fan in the standard cooling module rotates such that the standard CPU is not damaged and can be under segmented or non-segmented control. The calculation module 34 then acquires first fan-rotational-speed data D_{FAN1} corresponding to the power data by referring to the standard CPU power-fan rotational speed formula data. In the invention, the standard CPU power-fan rotational speed formula is stored in the memory 36.

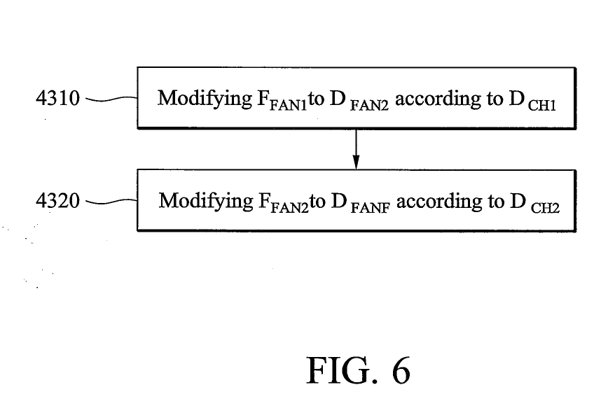

In step 430, the calculation module 34 modifies the first fan-rotational-speed data D_{FAN1} to final fan-rotational-speed data: D_{FAN} according to system characteristic data D_{CH}. FIG. 6 is a flowchart of the calculation module 34 modifying the first fan-rotational-speed data D_{FAN1} to the final fan-rotational-speed data D_{FAN} according to system characteristic data D_{CH} in accordance with an embodiment of the invention, comprising first system characteristic data D_{CH1} and second system characteristic data D_{CH2}. As shown, the calculation module 34 first modifies the first fan-rotational-speed data D_{FAN1} to a second fan-rotational-speed data D_{FAN2} according to the first system characteristic data D_{CH1} (step 4310), and then modifies the second fan-rotational-speed data D_{FAN2} to the final fan-rotational-speed data D_{FANF} according to the second system characteristic data D_{CH2} (step 4320).

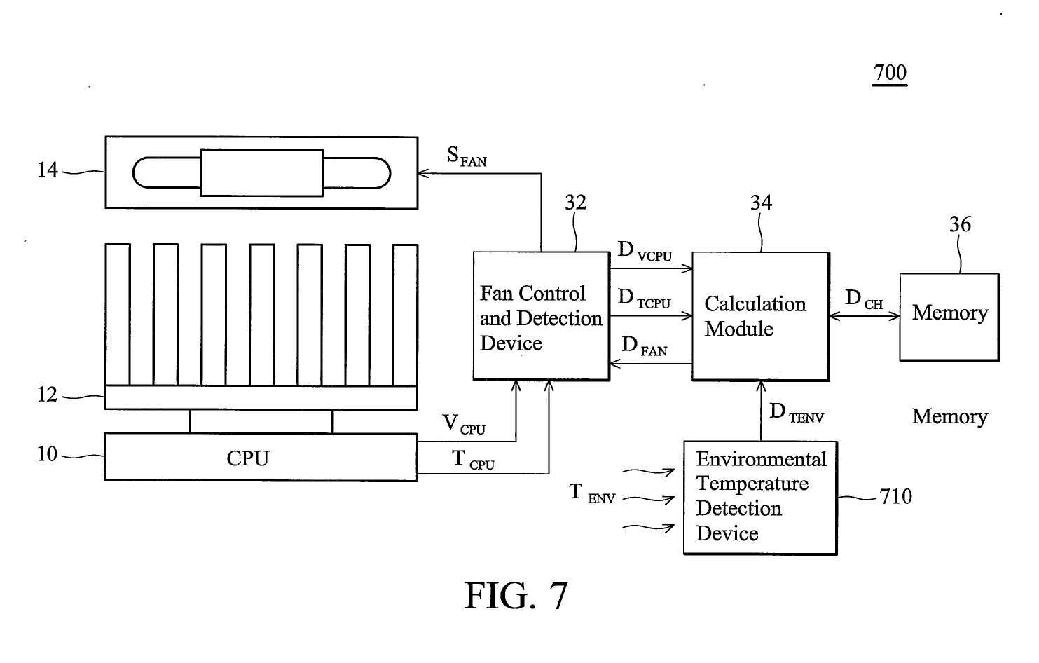

FIG. 7 shows an electronic system where system characteristic data D_{CH} comprises a cooling efficiency parameter and environmental temperature in accordance with an embodiment of the invention. The only difference between the electronic systems 300 and 700 is addition of an environmental temperature detection device 710 to detect the environmental temperature of the electronic system 700 and addition of a detection function of CPU temperature T_{CPU} in the fan control and detection device 32. The environmental temperature detection device 710 is preferably disposed near the cooling module.

At predetermined time(s), the environmental temperature detection device 710 detects the environmental temperature T_{ENV} of the electronic system 700 and provides environmental temperature data D_{TENV} to the calculation module 34. Additionally, the fan control and detection device 32 detects the temperature T_{CPU} of CPU 10 and then provides CPU temperature data D_{TCPU} to the calculation module 34 for use in calculating the cooling efficiency parameter by calculation module 34. The calculation module 34 then calculates and provides the cooling efficiency parameter to the memory 36.

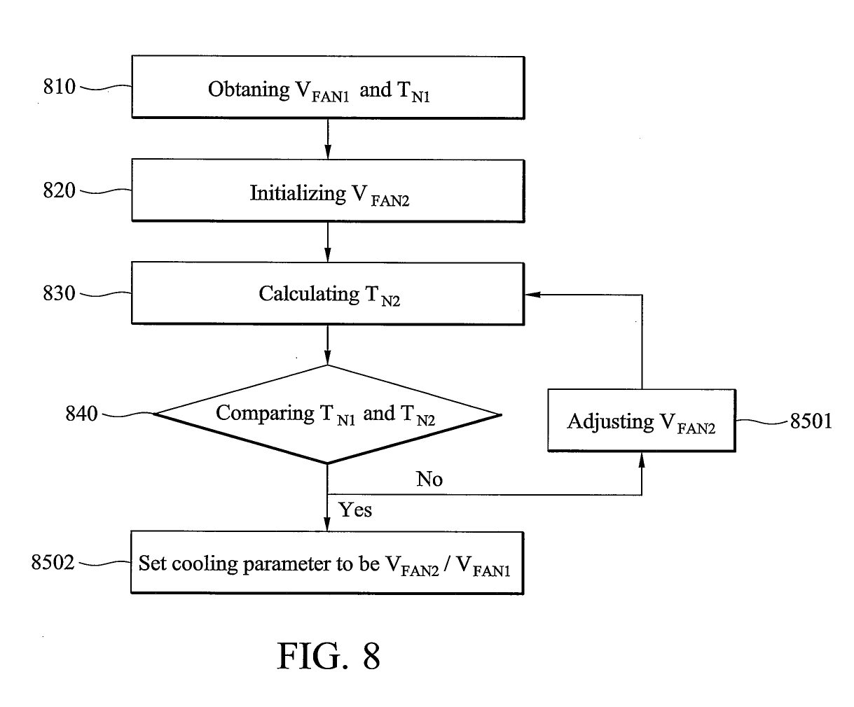

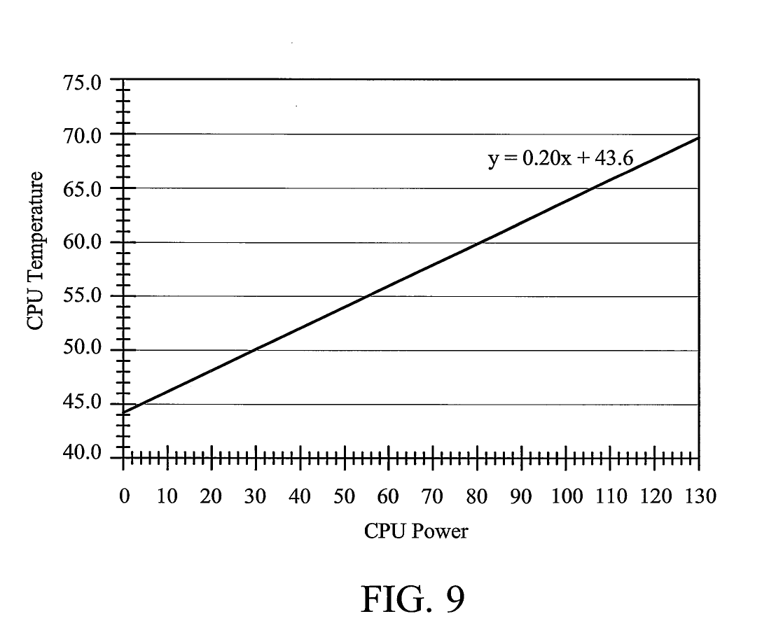

FIG. 8 is a flowchart of modulation module 34 calculating cooling efficiency parameter after receiving the environmental temperature data D_{TENV} and CPU temperature data D_{TCPU}. In the embodiment, the CPU temperatures in the electronic system 700 and the standard electronic system (described in the discussion on FIG. 3) are both converted to normalized temperature parameters irrelevant to CPU power and environmental temperature. When the rotational speed of the cooling fan 14 is adjusted such that the normalized temperature parameters of the electronic system 700 and the standard electronic system are equal, the ratio of the fan rotational speed in the electronic system 700 and that in the standard electronic system can provide cooling efficiency parameters. In an embodiment, a normalized temperature parameter is defined as
(T_{CPU}−T_{ENV}/T_{CPUT}),
where T_{CPU} denotes CPU temperature, T_{ENV} denotes environmental temperature, and T_{CPUT} denotes CPU theoretical temperature corresponding to CPU power in a CPU thermal curve. FIG. 9 shows an exemplary CPU thermal curve for a CPU.

In step 810 in FIG. 8, the calculation module 34 obtains the normalized temperature parameter T_{N1}, for the standard electronic system at the standard temperature and a predetermined CPU power, and a fan rotational speed V_{FN1} corresponding to the predetermined CPU power. In an embodiment, the memory 36 stores and provides the standard environmental temperature, the predetermined CPU power and CPU temperature to the calculation module 34 such that the calculation module 34 calculates the normalized temperature parameter. In another temperature, the memory 36 stores and provides the normalized temperature parameter T_{N1} of the standard electronic system to the calculation module 34 directly.

In step 820, the calculation module 310 outputs initial fan rotational speed data to the fan control and detection device 32 such that the cooling fan 14 rotates at an initial fan rotation speed represented by the initial fan rotational speed data.

In step 830, the calculation module obtains the normalized temperature parameter T_{N2} for the electronic system 700 according to the CPU temperature data D_{CUPT} received from the fan control and detection device 32, the power data, and the environmental temperature data D_{TENV} received from the environmental temperature detection device 710. The process of obtaining the normalized temperature parameter T_{N2} is similar to that of T_{N1}, and not repeated here for brevity.

In step 840, the calculation module 34 compares the normalized temperature parameters T_{N1} and T_{N2} to determine if the difference between them is below a predetermined error.

The calculation module 34 then performs different procedures dependent on the comparison result. When the difference between the normalized temperature parameters T_{N1} and T_{N2} exceeds the predetermined error (“No”), the calculation module 34 performs step 8501 to adjust the final fan-rotational-speed data to modify the fan rotational speed V_{FAN2} of the cooling fan 14 in the electronic system 700, such that the difference between T_{N1} and T_{N2} is decreased to fall below the predetermine error. More specifically, if the normalized temperature parameter is defined as formula (1), then when T_{N2}<T_{N1}, the fan rotational speed V_{FAN2} of the cooling fan 14 is decreased to increase T_{N2}, or otherwise, when T_{N2}>T_{N1}, the fan rotational speed V_{FAN2} of the cooling fan 14 is increased to decrease T_{N2}. The procedure then returns to step 830. When the difference between the normalized temperature parameters T_{N1}, and T_{N2} falls below the predetermined error (“Yes”), the calculation module 34 performs step 8502 to calculate V_{FAN2}/V_{FAN1} as a cooling efficiency parameter, wherein V_{FAN1} is predetermined fan rotational speed corresponding to the CPU power in the standard electronic system, and sequentially outputs the cooling efficiency parameter to the memory 36.

Since the normalized temperature parameter is independent of CPU power and environmental temperature, the cooling efficiency parameter is theoretically irrelevant to the detected environmental temperature and CPU power. Resultingly, the predetermined time during which information for the calculation of the normalized temperature parameter is obtained is the first time the electronic system 700 is used, or is determined by the designer or user and intermission between two predetermined times is long. Further, although the normalized temperature parameter is theoretically independent CPU power and environmental temperature, to enhance accuracy of the normalized temperature parameter, steps shown in FIG. 8 can be performed at different CPU power levels, and thus different cooling efficiency parameters corresponding to different CPU power values is obtained. These different cooling efficiency parameters can be further averaged to obtain an average cooling efficiency parameter. Alternatively, a plurality of CPU power ranges are designed, each corresponding to one of the different CPU power values. When the fan rotational speed is to be adjusted, it is necessary to detect which of the CPU power range where the current CPU power falls in order to pick up one of cooling efficiency parameters for use.

Turning back to FIG. 6, the following paragraphs illustrate how the calculation module 34 modifies the first fan rotational speed data D_{FAN1} to the second fan rotational speed data D_{FAN2} using the cooling efficiency parameter in step 4310. In an embodiment, the calculation module 34 multiplies a first fan rotational speed represented by first fan rotational speed data by the cooling efficiency parameter and obtains a second fan rotational speed represented by second fan rotational speed data.

Referring now to FIG. 7, the following paragraphs illustrate process to obtain environmental temperature data D_{TENV}. At second predetermined time(s), the environmental temperature detection device 710 detects the environmental temperature of the electronic system 700 and provides environmental temperature data D_{TENV} to the calculation module 34 to modify fan rotational speed by the calculation module 34. The environmental temperature data D_{TENV} is also provided to and stored in the memory 36. Because the second predetermined time is only related to environmental temperature, the second predetermined time can be set as the first time the electronic system 700 operates, and the interval between two second predetermined times can be very long, such as one or several months.

Referring back to FIG. 6, the following paragraphs illustrate how calculation module 34 modifies second fan-rotational-speed data D_{FAN2} to final fan-rotational-speed data D_{FANF} according to second system characteristic data D_{CH2}. In one embodiment, the memory 36 stores the standard environmental temperature corresponding to the normalized temperature parameter of the standard electronic system. The calculation 34 modifies the second fan-rotational-speed data D_{FAN2} to the final fan-rotational-speed data D_{FANF} according to the difference between the environmental temperature T_{ENV} and the standard environmental temperature. For example, the memory further can further store a plurality of temperature ranges and a plurality of fan rotational speed adjusted quantities, each corresponding to one of the temperature ranges. The calculation module 34 detects the temperature ranges in shich the difference between the environmental temperature T_{ENV} and the standard environmental temperature falls, adds the second fan-rotational-speed by the corresponding fan rotational speed adjusted quantity, and then obtains the final fan-rotational-speed data D_{FANF}.

In the embodiments, the calculation module 34 first modifies the first fan-rotational-speed data D_{FAN1} to a second fan-rotational-speed data D_{FAN2} according to the cooling efficiency parameter, and then modifies the second fan-rotational-speed data D_{FAN2} to the final fan-rotational-speed data D_{FANF} according to the environmental temperature data D_{TENV}. However, it should be clear to those skilled in the art that the calculation module 34 first modifies the first fan-rotational-speed data D_{FAN1} to a second fan-rotational-speed data D_{FAN2} according to the environmental temperature data D_{TENV}, and then the second fan-rotational-speed data D_{FAN2} to the final fan-rotational-speed data D_{FANF} according to the cooling efficiency parameter.

Since the fan rotational speed of the cooling fan is adjusted based on CPU power, the fan rotational speed can be adjusted promptly according to the CPU condition. Further, the invention modifies the fan rotational speed according to system characteristics such as cooling efficiency of cooling module and environmental temperature. Accordingly, irrespective of the cooling efficiency of the cooling module, basic and minimum cooling requirements of the CPU can be satisfied and the fan rotational speed control can be achieved perfectly.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for controlling fan rotational speed in an electronic system comprising a CPU and a cooling module comprising a cooling fan and a cooling fin, the method comprising:
measuring the central voltage of the CPU to obtain the CPU power; and
obtaining a first fan rotational speed according to the CPU power; and
modifying the first fan rotational speed according to system characteristic data of the electronic system.

2. The method of claim 1, wherein the measuring step comprises measuring the central voltage of the CPU and then obtaining the CPU power by referring the measured central voltage to a CPU load curve of the CPU.

3. The method of claim 1, wherein the system characteristic data comprises cooling efficiency parameter of the cooling module.

4. The method of claim 1, wherein the system characteristic data comprises environmental temperature of the electronic system.

5. The method of claim 1, wherein the first fan rotational speed is predetermined corresponding to the CPU power at a standard environmental temperature in a standard electronic system comprising a standard CPU allocated with a standard cooling module.

6. The method of claim 5, wherein system characteristic data comprises cooling efficiency parameter of the cooling module and the environmental temperature of the electronic system.

7. The method of claim 3, wherein the modifying step comprises: modifying the first fan rotational speed into a second fan rotational speed according to the cooling efficiency parameter of the cooling module and modifying the second fan rotational speed according to the environmental temperature or modifying the first fan rotational speed into a second fan rotational speed according to the environmental temperature and modifying the second fan rotational speed according to the cooling efficiency parameter of the cooling module.

8. The method of claim 7, wherein the cooling efficiency parameter is the ratio of the rotational speeds of the fans in the cooling module and the standard cooling module when normalized temperature parameters of the electronic system and the standard electronic system are equal, wherein the normalized temperature parameter is a normalized CPU temperature independent of CPU power and environmental temperature.

9. The method of claim 7, wherein the normalized temperature parameter is (T_{CPU}−T_{ENV})/T_{CPUT}, where T_{CPU} is CPU temperature, T_{ENV} is environmental temperature, and T_{CPUT} is a theoretical CPU temperature corresponding to CPU power in a CPU thermal curve formula.

10. The method of claim 8, wherein modifying the first fan rotational speed to a second fan rotational speed according to the cooling efficiency parameter of the cooling module comprises multiplying the first fan rotational speed to the cooling efficiency parameter of the cooling module and then obtaining the second fan rotational speed; and
wherein modifying the second fan rotational speed according to the cooling efficiency parameter of the cooling module is multiplying the by the cooling efficiency parameter of the cooling module to the second fan rotational speed.

11. The method of claim 7, wherein modifying the first or second fan rotational speed according to the environmental temperature comprises modifying the first or second fan rotational speed according to the difference between the environmental temperature of the electronic system and the standard environmental temperature of the standard electronic system.

12. The method of claim 11, wherein modifying the first or second fan rotational speed according to the difference between the environmental temperature of the electronic system and the standard environmental temperature of the standard electronic system comprises:
determining which of the a plurality of temperature regions where the difference between the environmental temperature of the electronic system and the standard environmental temperature of the standard electronic system falls, wherein each of the temperature regions corresponds to a fan rotational speed adjusted quantity; and
adding the first or second fan rotational speed by the fan rotational speed adjusted quantity corresponding to the determined temperature region.

13. An electronic system, comprising:
a CPU;
a cooling module comprising a cooling fan and a cooling fin;
a fan control and detection device coupled to the CPU and the cooling fan, detecting the central voltage of the CPU to output a voltage data, and controlling the rotational speed of the fan according to a final fan rotational speed data;
a memory storing system characteristic data; and
a calculation module coupled to the fan control and detection device to produce the final fan rotational speed data according to the voltage data and the system characteristic data.

14. The electronic system of claim 13, wherein the calculation module is a BIOS cooperating with an environmental monitor device inherent in the electronic system, or a combination of conventional logic components, or a single chip computer integrated with conventional logic components.

15. The electronic system of claim 13, wherein the system characteristic data comprises cooling efficiency parameter of the cooling module.

16. The electronic system of claim 13, wherein the system characteristic data comprises environment of the electronic system.

17. The electronic system of claim 13, wherein the calculation module producing the final fan rotational speed data according to the voltage data and the system characteristic data comprises:
producing power data of the CPU according to the voltage data;
producing first fan rotational speed data according to the power data; and
modifying the first fan rotational speed data to the final fan rotational speed data according to the system characteristic data

18. The electronic system of claim 17, wherein the memory further stores CPU load curve data, and the calculation module produces the power data according to the voltage data and the CPU load curve data.

19. The electronic system of claim 17, wherein the memory further stores standard CPU power-fan rotational speed formula data and a standard environmental temperature, data on predetermined fan rotational speeds corresponding to different power for a standard CPU of the same type of the CPU allocated with a standard cooling module in a standard electronic system at the standard environmental temperature.

20. The electronic system of claim 19, wherein the system characteristic data comprises cooling efficiency parameter of the cooling module and the environmental temperature of the electronic system.

21. The electronic system of claim 20, wherein the calculation module modifies the first fan rotational speed to a second fan rotational speed according to the cooling efficiency parameter of the cooling module and then modifying the second fan rotational speed according to the environmental temperature or modifies the first fan rotational speed to a second fan rotational speed according to the environmental temperature and then modifying the second fan rotational speed according to the cooling efficiency parameter of the cooling module.

22. The electronic system of claim 20, wherein the cooling efficiency parameter is the ratio of the rotational speeds of the fans in the cooling module and the standard cooling module when normalized temperature parameters of the electronic system and the standard electronic system are equal, wherein the normalized temperature parameter is a normalized CPU temperature independent of CPU power and environmental temperature.

23. The electronic system of claim 22, further comprising an environmental temperature detection device to detect the environmental temperature of the electronic system;
wherein the fan control and detection module detects the CPU temperature;
wherein the calculation module obtains the normalized temperature parameter of the standard electronic system at the standard temperature with the standard CPU operating therein at a predetermined power level and the fan rotational speed corresponding to the predetermined power; and
wherein the calculation module generates the cooling efficiency parameter by:
(1) outputting an initial value of a fan rotational speed data to the fan control and detection device;
(2) calculating the normalized temperature parameter of the electronic system according to the CPU temperature received from the fan control and detection device and the CPU power and the environmental temperature received from the environ mental temperature detection device;
(3) determining the difference between the normalized temperature parameters of the electronic system and the standard electronic system is below a predetermined value; and
(4) if the difference between the normalized temperature parameters of the electronic system and the standard electronic system exceeds the predetermined error, adjusting the fan rotational speed data, outputting the adjusted fan rotational speed data to the fan control and detection device and returning to step (2), or storing the ratio of the rotational speeds of the electronic system and the standard electronic system as the cooling efficiency parameter.

24. The electronic system of claim 23, wherein the calculation module calculates the normalized temperature parameter according to the predetermined power, the standard temperature, the CPU temperature of the standard CPU when operating with the predetermined power along with the standard fan rotating with the predetermined rotational speed at the standard temperature, all stored in the memory, or the memory stores the normalized temperature parameter of the standard electronic system and the calculation module acquires the normalized temperature parameter of the standard electronic system from the memory.

25. The electronic system of claim 24, wherein the normalized temperature parameter is (T_{CPU}−T_{ENV})/T_{CPUT}, where T_{CPU} is CPU temperature, T_{ENV} is environmental temperature of the electronic system, and T_{CPUT} is a theoretical CPU temperature corresponding to CPU power in a CPU thermal curve formula.

26. The electronic system of claim 22, wherein the calculation module modifies the first fan rotational speed to a second fan rotational speed according to the cooling efficiency parameter of the cooling module by multiplying the first fan rotational speed to the cooling efficiency parameter of the cooling module and then obtaining the second fan rotational speed; and
wherein the calculation module modifies the second fan rotational speed according to the cooling efficiency parameter of the cooling module by multiplying the cooling efficiency parameter of the cooling module to the second fan rotational speed.

27. The electronic system of claim 21, wherein the calculation module modifies the first or second fan rotational speed according to the environmental temperature by modifying the first or second fan rotational speed according to the difference between the environmental temperature of the electronic system and the standard environmental temperature of the standard electronic system.

28. The electronic system of claim 27,
wherein the memory further stores a plurality of temperature regions and a plurality of fan rotational speed adjusted quantities each corresponding to one of the temperature regions; and
wherein the process calculation module modifies the first or second fan rotational speed according to the difference between the environmental temperature of the electronic system and the standard environmental temperature of the standard electronic system comprises:
determing which of a plurality of temperature regions where the difference between the environmental temperature of the electronic system and the standard environmental temperature of the standard electronic system falls,
wherein each of the temperature regions corresponds to a fan rotational speed adjusted quantity; and
adding the fan rotational speed adjusted quantity corresponding to the determined temperature region to the first or second fan rotational speed.
